(19) United States
(12) Patent Application Publication
(10) Pub. No.: US 2016/0266974 A1
(43) Pub. Date: Sep. 15, 2016

(54) MEMORY CONTROLLER, DATA STORAGE DEVICE AND DATA WRITE METHOD

(71) Applicant: Kabushiki Kaisha Toshiba, Minato-ku (JP)

(72) Inventors: Jun ICHISHIMA, Kamakura (JP); Kenji Yoshida, Kamakura (JP); Yoriharu Takai, Hiratsuka (JP); Susumu Yamazaki, (US); Norifumi Tsuboi, Yokohama (JP)

(73) Assignee: Kabushiki Kaisha Toshiba, Minato-ku (JP)

(21) Appl. No.: 14/753,780

(22) Filed: Jun. 29, 2015

(30) Foreign Application Priority Data
Mar. 10, 2015 (JP) 2015-047184

(51) Int. Cl. G06F 11/10; G06F 3/06; G11C 29/52

(52) U.S. Cl. CPC G06F 11/1072; G11C 29/52; G06F 3/0619; G06F 3/064; G06F 3/0679

(57) ABSTRACT

According to one embodiment, a memory controller includes a bank controller including a queuing part queuing commands associated with a bank and having a first flag associated with each of the commands, the bank controller executing the commands in order, a data controller transferring write data to the bank when a particular command to be executed among the commands is a write command associated with one of physical addresses in the bank, and a parity controller generating parity data for restoring the write data based on a value of a first flag associated with the particular command, before execution of the particular command is completed.

### CROSS-REFERENCE TO RELATED APPLICATIONS

This application is based upon and claims the benefit of priority from Japanese Patent Application No. 2015-047184, filed Mar. 10, 2015, the entire contents of which are incorporated herein by reference.

### FIELD

Embodiments described herein relate generally to a memory controller, a data storage device and a data write method.

### BACKGROUND

In a nonvolatile semiconductor memory serving as a storage part of a data storage device, for example, a NAND flash memory, parity data corresponding to write data is generated. Thus, even if the written data is unintentionally lost, the nonvolatile semiconductor memory can restore the lost data. Also, if the parity data is stored along with the write data in the nonvolatile semiconductor memory, it is possible to protect the write data even after writing.

For example, suppose the nonvolatile semiconductor memory is a multi-level nonvolatile semiconductor memory including, for example, n-level cells each of which can store n-bit data (n is a natural number of two or more). In this multi-level nonvolatile semiconductor memory, data to be written to n logical addresses included in a single physical address can be restored by n parity generation circuits included in a memory controller.

Also, in order to write data to the n logical addresses in the single physical address, it is necessary to perform writing n times (in first to n^{th} stages). In this case, in n writes to the n logical addresses, the memory controller repeatedly transfers same write data to the nonvolatile semiconductor memory. Thus, parity data associated with the n logical addresses is generated based on write data transferred in one of the n writes.

However, in recent years, with respect to multi-level nonvolatile semiconductor memories, it has been restudied in order to increase the writing speed in what order data should be written to a plurality of physical addresses (each including n logical addresses).

In this case, it should be noted that unless generation of parity data in a memory controller and transfer of write data and parity data from the memory controller to the nonvolatile memory mesh well with each other, data cannot be efficiently transferred, and as a result, the writing speed is reduced.

### BRIEF DESCRIPTION OF THE DRAWINGS

FIG. 1 is a view showing a memory controller according to a first embodiment;

FIG. 2 is a view showing an example of a bank controller according to the first embodiment;

FIGS. 3 and 4 are views showing an example of a data write method in the first embodiment;

FIG. 5 is a view showing a memory controller according to a second embodiment;

FIG. 6 is a view showing an example of a bank controller according to the second embodiment;

FIGS. 7 and 8 are views showing an example of a procedure for executing a command;

FIGS. 9 to 11 are views showing an example of the timing of generating parity data;

FIG. 12 is a view showing an example of a portable computer;

FIG. 13 is a view showing an example of a data storage device; and

FIG. 14 is a view showing an example of a hybrid data storage device.

### DETAILED DESCRIPTION

In general, according to one embodiment, a memory controller comprises: a bank controller comprising a queuing part configured to queue commands associated with a bank and having a first flag associated with each of the commands, the bank controller executing the commands in order; a data controller configured to transfer write data to the bank when a particular command to be executed among the commands is a write command associated with one of physical addresses in the bank; and a parity controller configured to generate parity data for restoring the write data based on a value of a first flag associated with the particular command by a time the particular command is completed. A write associated with each physical addresses is executed by stages, parity data for restoring write data of the physical addresses is generated in an initial stage among the stages when the physical addresses are included in an initial parity group, and parity data for restoring write data of the physical addresses is generated in an any stage among the stages when the physical addresses are included in a parity group except the initial parity group.

Embodiments will be described hereinafter with reference to the accompanying drawings.

### 1. FIRST EMBODIMENT

(1) Memory Controller

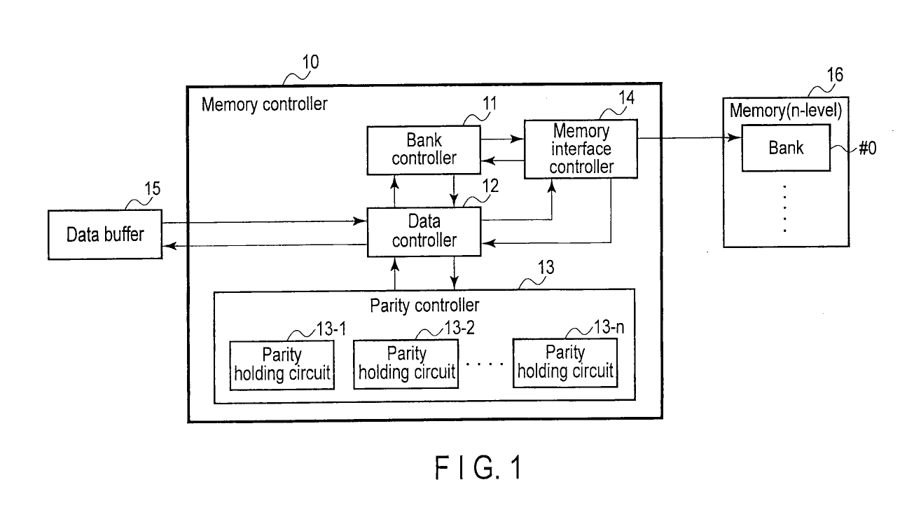

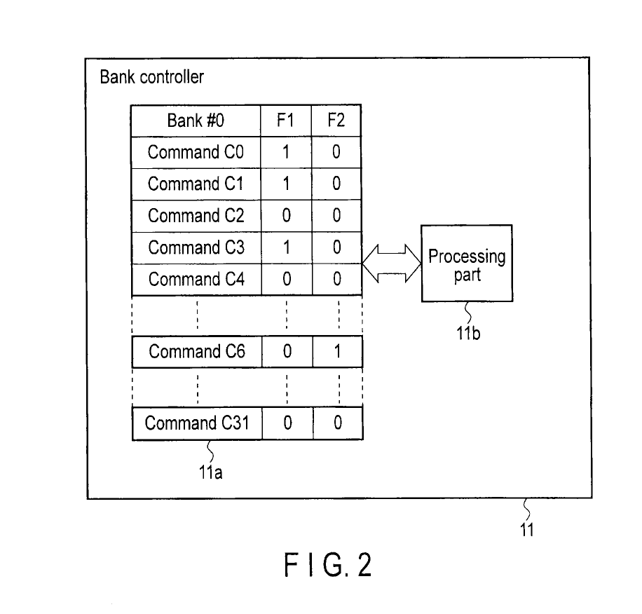

FIG. 1 shows a memory controller according to the first embodiment. FIG. 2 shows an example of a bank controller according to the first embodiment.

To be more specific, a memory controller 10 includes a bank controller 11, a data controller 12, a parity controller 13 and a memory interface controller 14.

The bank controller 11, as shown in FIG. 2, includes, for example, a queuing part 11a which queues a plurality of commands C0 to C31 to bank #0 in a memory, for example, a NAND flash memory 16, and a processing part 11b which executes the commands C0 to C31 in turn.

The queuing part 11a includes flags F1 and F2 which are associated with the commands C0 to C31.

Each of the flags F1 indicates whether to generate parity data during execution of an associated entered command or not. To be more specific, when the flag F1 is set (active), for example, it is 1, the parity data is generated during execution of an associated entered command; however, on the other hand, when the flag F1 is clear (non-active), for example, it is 0, the parity data is not generated during execution of the entered command.

In an example shown in the FIG. 2, the flags F1 associated with the commands C0, C1 and C3 of the commands C0-C31 queued by the queuing part 11a are set. Therefore, during execution of the commands C0, C1 and C3, the parity data is generated.

Each of the flags F2 indicates whether to write the parity data to the bank #0 or not. To be more specific, when the flag F2 is set (active), for example, it is 1, the parity data is written to the bank #0; however, on the other hand, when the flag F2 is clear (non-active), for example, it is 0, parity data is not written to the bank #0.

In the example shown in the FIG. 2, the flag F2 associated with the command C6 of the queued commands C0-C31 is set. Therefore, in response to the command C6, the parity data is written to the bank #0.

If an entered command to be executed, for example, the command C0 as shown in the FIG. 2, is a write command to one of a plurality of physical addresses in the bank #0, the data controller 12 transfers write data in a data buffer (for example, a DRAM or MRAM) 15 to the bank #0 in the memory 16.

Also, if the entered command to be executed, for example, the command C6 as shown in the FIG. 2, is a write command to write the parity data, and the flag F2 associated with the command C6 is set, the parity data is transferred to the bank #0 in response to the command C6.

If the flag F1 associated with an entered command to be executed of the commands C0 to C31 is active, the parity controller 13 generates party data for restoring write data to be transferred to bank #0 during execution of the command.

If the memory 16 is an n-level memory in which n-bit data (n is a natural number of 2 or more) can be stored in each of memory cells, each of a plurality of physical addresses in bank #0 includes n logical addresses in order that for example, n page data could be stored.

Furthermore, the parity controller 13 comprises n parity holding circuits 13-1, 13-2, . . . 13-n. To be more specific, the parity controller 13 can hold n parity data for restoring write data (n level) to be written to n physical addresses, using the n parity holding circuits 13-1, 13-2, . . . .

The memory interface controller 14 controls transmission and reception of data between the memory controller 10 and the memory 16. For example, in writing, the memory interface controller 14 transmits write data to the bank #0 in the memory 16. Furthermore, in reading, the memory interface controller 14 receives data read from the bank #0 in the memory 16.

The memory 16 may include a plurality of banks. In this case, each of the plurality of banks may be provided as a single block in a single nonvolatile semiconductor memory (1 chip). Also, the plurality of banks may be provided as a plurality of nonvolatile semiconductor memories (chips).

(2) Data Write Method

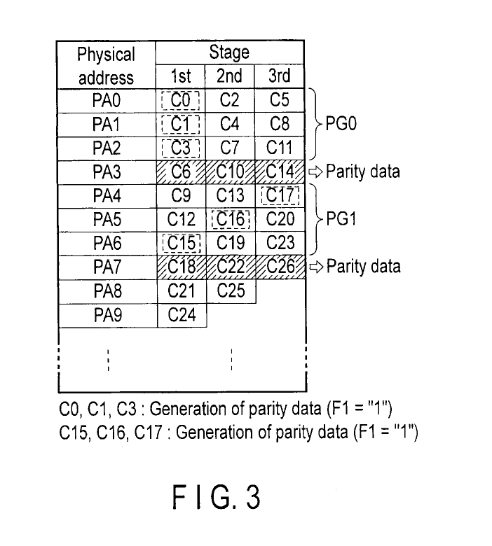

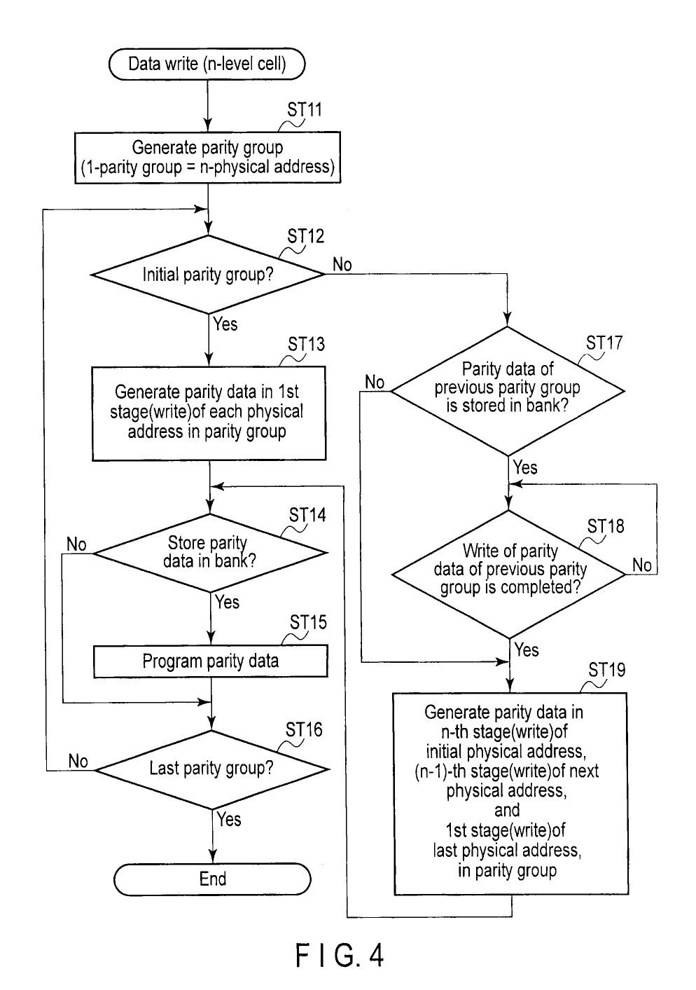

FIGS. 3 and 4 show an example of a method of writing data with the memory controller as shown in FIG. 1.

This data write method is applied to the case where for example, a single bank includes a plurality of parity groups each of which includes n physical addresses (n is a natural number of 2 or more) each including n logical addresses.

It should be noted that each of the parity groups is a group of physical addresses. The physical addresses may be consecutive (e.g., 0, 1, 2, . . . ) or non-consecutive (0, 2, 4, . . . )

All parity data for restoring write data to be written to the above physical addresses is stored at a single address. Therefore, if a single physical address includes n logical addresses, it is preferable that a single parity group include n physical addresses.

In order that the following explanation be simplified, it is given by referring to the case where n is three, that is, a single parity group includes three physical addresses, and each of the three physical addresses includes three logical addresses.

In the above case, writing to each of a plurality of physical addresses PA0-PA9 is completed through first to third stages.

In each of the first to third stages, three page data including low-order page data, intermediate page data and high-order page data is transferred from the memory controller to the bank in the memory. This means that three page data is transferred three times to the bank in the memory to complete writing to a single physical address.

First, if a write command is issued, a parity group is generated (step ST11 in FIG. 4).

The bank controller 11 generates a parity group in response to a request to generate a parity group. In the above case, the bank controller 11 generates parity groups each including three physical addresses. For example, as shown in FIG. 3, a parity group PG0 includes three physical addresses PA0, PA1 and PA2, and a parity group PG1 includes three physical addresses PA4, PA5 and PA6.

Thereafter, the bank controller 11 executes in turn a plurality of commands (commands C0-C26) queued by the queuing part.

The command C0 is a write command associated with the physical address PA0. Thus, if an entered command to be executed is the command C0, 3 page data to be written to the physical address PA0 is transferred to the bank of the memory (first stage).

The command C1 is a write command associated with the physical address PA1. Therefore, if the entered command to be executed is the command C1, three page data to be written to the physical address PA1 is transferred to the bank of the memory (first stage).

The command C2 is a write command associated with the physical address PA0. Therefore, if the entered command to be executed is the command C2, three page data to be written to the physical address PA0 is transferred to the bank of the memory (second stage).

The command C3 is a write command associated with the physical address PA2. Therefore, if the entered command to be executed is the command C3, three page data to be written to the physical address PA2 is transferred to the bank of the memory (first stage).

The command C4 is a write command associated with the physical address PA1. Therefore, if the entered command to be executed is the command C4, three page data to be written to the physical address PA1 is transferred to the bank of the memory (second stage).

The command C5 is a write command associated with the physical address PA0. Therefore, if the entered command to be executed is the command C5, three page data to be written to the physical address PA0 is transferred to the bank of the memory (third stage).

Then, it is confirmed whether the entered command to be executed is a write command associated with a physical address in the first parity group PG0 or not (step ST12 in FIG. 4).

If the entered command to be executed is a write command associated with a physical address in the parity group PG0, parity data is generated in first stages of writing to all the physical addresses PA0, PA1 and PA2 in the parity group PG0 (step ST13 in FIG. 4).

For example, as shown in FIG. 2, if the entered command to be executed is the command C0, parity data for restoring three page data to be written to the physical address PA0 is generated during execution of the command C0 (first stage), by setting a flag F1 associated with the command C0.

Similarly, if entered commands to be executed are the commands C1 and C3, parity data for restoring three page data to be written to the physical addresses PA1 and PA2 is generated during execution of the commands C1 and C3 (first stage), by setting flags F1 associated with the commands C1 and C3.

Thereafter, it is confirmed whether or not three parity data associated with the first parity group PG0, which is generated during execution of the commands C0, C1 and C3, is to be stored in the bank (step ST14 in FIG. 4).

If it is confirmed that the three parity data is to be stored in the bank, the three parity data is stored (step ST15 in FIG. 4).

For example, as shown in FIG. 3, the above 3 parity data is stored at three logical addresses in the physical address PA3.

That is, in response to the commands C6, C10 and C14, parity data associated with physical addresses PA0, PA1 and PA2 is written to the physical address PA3.

It should be noted that writes of all parity data associated with the first parity group PG0 are completed when execution of the commands C6, C10 and C14 is completed.

In the above case, before completion of writes at all physical addresses PA0, PA1 and PA2 in the parity group PG0, it is possible to start to write parity data associated with the first parity group PG0. For example, the commands C6 and C10, which are commands to write parity data, are executed before execution of the command C11, which is the last one of the write commands associated with the physical addresses PA0, PA1 and PA2 in the parity group PG0.

Furthermore, in the above case, before completion of writes of all the parity data associated with the parity group PG0, it is possible to start to write data to physical addresses PA4 and PA5 in the parity group PG1 subsequent to the parity group PG0. For example, the commands C9, C12 and C13, which are write commands to physical addresses PA4 and PA5 in the parity group PG1, are executed before execution of the command C14, which is a command to write the last parity data associated with the parity group PG0.

However, if the entered commands to be executed are commands C9, C12 and C13, as described later, parity data associated with the parity group PG1 cannot be generated during execution of the commands C9, C12 and C13.

This is because the party controller must hold the parity data associated with the parity group PG0 until writing of the parity data associated with the parity group PG0 is completed.

To be more specific, if the entered command to be executed is a write command associated with a physical address in a parity group (the parity group GP1 in this case) subsequent to a first parity group (the parity group PG0 in this case), it is confirmed whether or not parity data associated with the first parity group is to be stored in the bank of the memory (steps ST12 and ST17 in FIG. 4).

If it is confirmed that the parity data associated with the first parity group is to be stored in the bank of the memory, and then if the parity data has been all stored (writes of the parity data have been all completed), it is permitted to generate parity data associated with the subsequent parity group (step ST18 in FIG. 4).

For example, in the case shown in FIG. 3, it is completed to write the parity data associated with the parity group PG0, when execution of the command C14 is completed. Therefore, parity data associated with the parity group PG1 is generated when the command C15 or a command issued later than the command C15 is executed.

If the entered command to be executed is a write command associated with a physical address in a parity group subsequent to the first parity group, i.e., in the above case, it is a write command associated with a physical address in the parity group PG1 subsequent to the parity group PG0, three parity data is generated at the following respective timings: a third stage of writing to a first physical address PA4 in the parity group PG1; a second stage of writing to a subsequent physical address PA5 in the parity group PG1; and a first stage of writing to a last physical address PA6 in the parity group PG1 (step ST19 in FIG. 4).

For example, in the case shown in FIG. 3, if the entered command to be executed is the command C15, parity data for restoring three page data to be written to the physical address PA6 is generated during execution of the command 15 (first stage) by activating the flag F1 associated with the command C15.

Similarly, if the entered commands to be executed are the commands C16 and C17, parity data for restoring three page data to be written to the physical addresses PA5 and PA4 is generated during execution of the commands C16 and C17 (second and third stages), by setting flags F1 associated with the commands C16 and C17.

Then, it is confirmed whether the three parity data generated during execution of the commands C15, 16 and 17 is to be stored in the bank or not (step ST14 in FIG. 4).

If it is confirmed that the three parity data is to be stored in the bank, the three parity data is stored in the bank (step ST15 in FIG. 4).

For example, as shown in FIG. 3, the three parity data is stored at three logical addresses in the physical address PA7.

That is, in response to the commands C18, C22 and C26, parity data associated with physical addresses PA6, PA7 and PA8 is written to the physical address PA7.

Then, if it is confirmed that writing of parity data associated with the last parity group is completed, the data write operation of the first embodiment ends (step ST16 in FIG. 4).

It should be noted that in the first embodiment, parity data associated with the parity group PG0, which includes physical addresses PA0 to PA2, is stored at the physical address PA3; and parity data associated with the parity group PG1, which includes physical addresses PA4 to PA6, is stored at the physical address PA7.

However, the way of storing parity data is not limited to the above way. For example, parity data associated with the parity groups PG0 and PG1 may be stored in areas other than the areas of the physical addresses PA3 and PA7, i.e., at physical addresses different from the physical addresses PA3 and PA7 in the same bank as in the physical addresses PA3 and PA7, or at physical addresses in another bank, or at physical addresses in a bank in another nonvolatile semiconductor memory.

By virtue of the above data write operation, each of write data and parity data is transferred efficiently.

For example, in the above case, as to the first parity group PG0, parity data for restoring data to be written to the physical addresses PA0 to PA2 is all generated in the first stage. In this case, generation of all the parity data ends when execution of the command C3 is completed, and writing of the parity data can be started from execution of the command C4.

Furthermore, as to a parity group other than the first parity group PG0, for example, as to the parity group PG1, parity data for restoring data to be written to the physical addresses PA4 to PA6 is generated in different stages (first to third stages). In this case, generation of all the parity data is completed when execution of the command C17 is completed, and writing of the parity data can be started from execution of the command C18.

Such a data write method is advantageous to, especially, the case where in a multichannel system in which a plurality of banks can be accessed at the same time, parity data is stored subsequent to user data.

This will be explained in the item “example of application”.

(4) Conclusion

According to the first embodiment, each of write data and parity data can be transferred efficiently.

### 2. SECOND EMBODIMENT

(1) Memory Controller

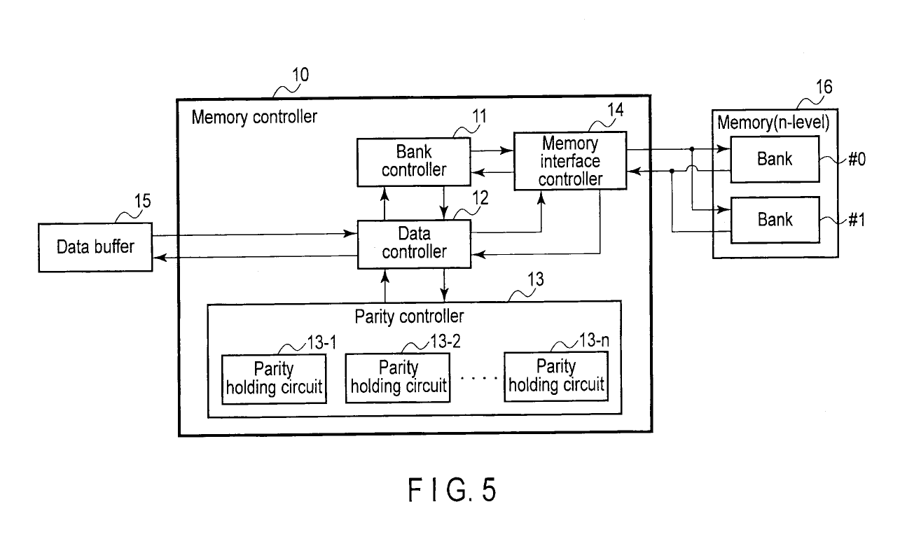

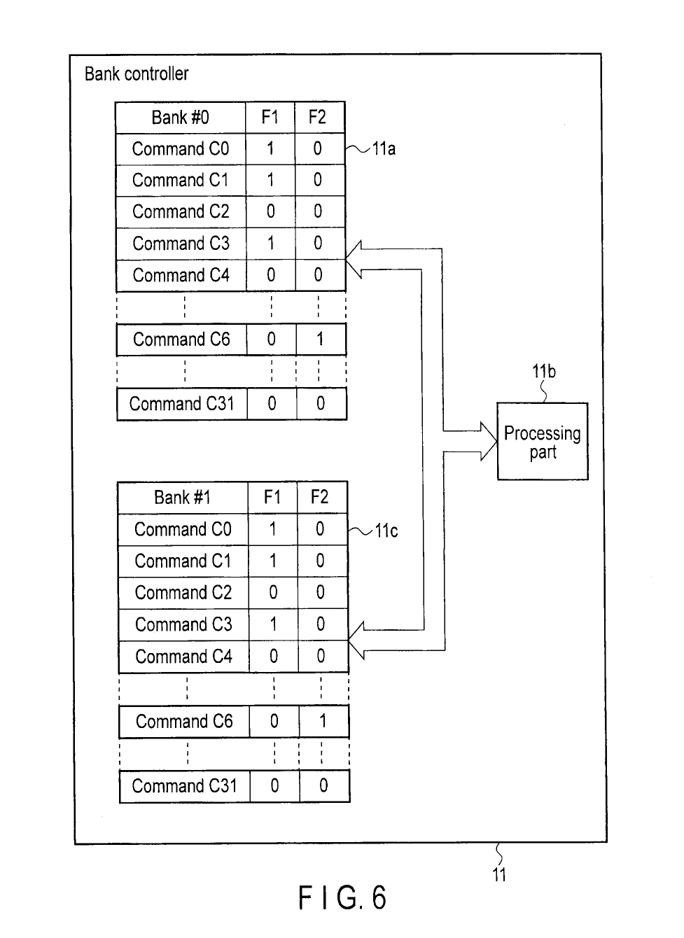

FIG. 5 shows a memory controller according to the second embodiment. FIG. 6 shows an example of a bank controller.

Unlike the first embodiment, the second embodiment can be applied to a multichannel system in which a memory controller 10 can access banks #0 and #1 in a memory 16 at the same time. With respect to the second embodiment, only elements different from those in the first embodiment will be explained; and elements identical to those in the first embodiment will be denoted by the same reference numerals as in the first embodiment, and their detailed explanations will be omitted.

It should be noted that in the second embodiment, the number of banks is two (banks #0 and #1); however, it may be three or more.

To be more specific, a memory controller 10 comprises a bank controller 11, a data controller 12, a parity controller 13 and a memory interface controller 14.

The bank controller 11, as shown in, for example, FIG. 6, comprises a queuing part 11a which queues commands C0 to C31 to the bank #0 in the memory 16 (for example, a NAND flash memory), a queuing part 11c which queues commands C0 to C31 to the bank #1 in the memory 16, and a processing part 11b which executes in turn the commands C0 to C31 queued by the queuing parts 11a and 11c.

The queuing parts 11a and 11c each include flags F1 and F2 each of which is associated with the commands C0 to C31.

Each of the flags F1 indicates whether to generate parity data during execution of an associated entered command or not. Each of the flags F2 indicates whether to write parity data to the bank #0 or #1 or not. Since the flags F1 and F2 are referred to in the explanation of the first embodiment, they are not referred to in the following explanation of the second embodiment.

In the second embodiment, in writing, the processing part 11b can transfer data to the banks #0 and #1 in parallel. However, the processing part 11b stops or restarts execution of a command to one of the banks #0 and #1 in accordance with an executed state of a command associated with the other bank. For example, the processing part 11b changes the timing of generating parity data for one of the banks #0 and #1 in accordance with whether parity data for the other bank is generated or transferred. Also, the processing part 11b stops or restarts generation of the parity data for one of the banks #0 and #1 in accordance with whether the parity data for the other bank is generated or transferred.

(2) Procedure for Execution of Command

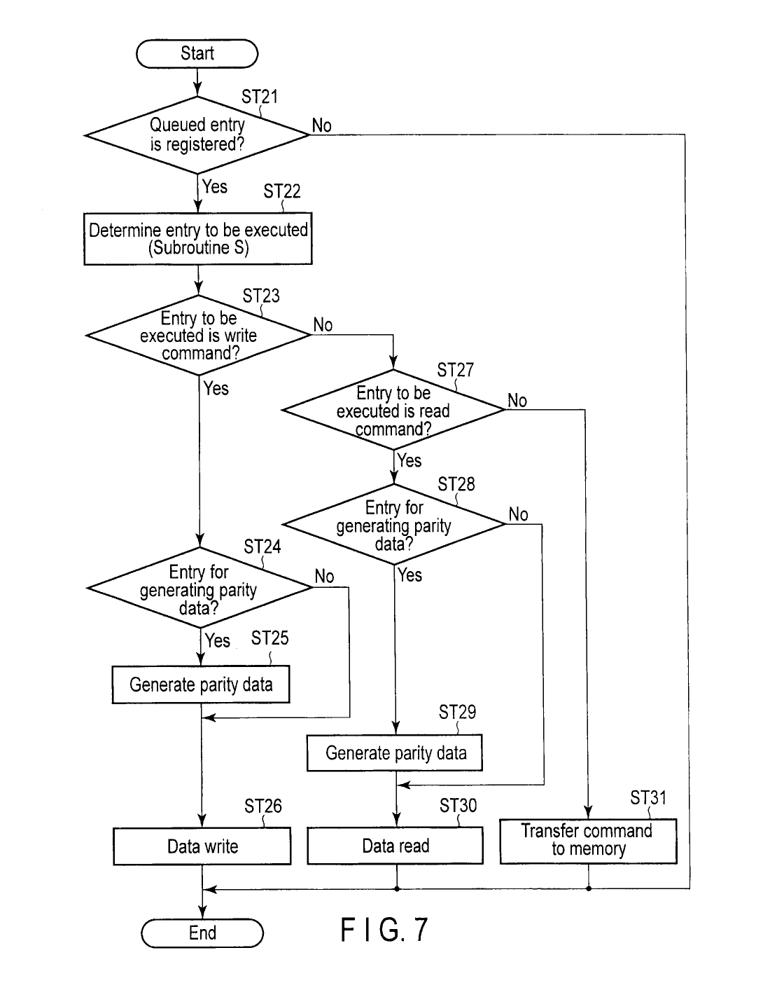

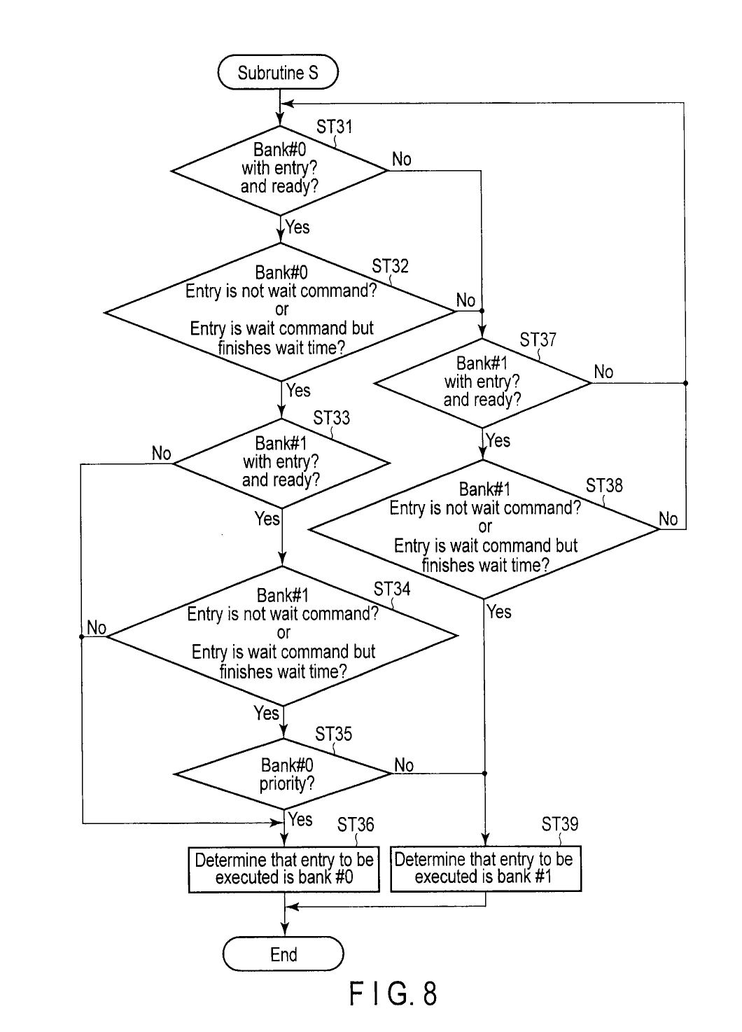

FIGS. 7 and 8 show a procedure of execution of a command by the memory controller as shown in FIG. 5.

As shown in FIG. 7, first, it is confirmed whether a queued command or commands are entered or not (step ST21). If the queued commands are entered, it is determined which of the entered commands is to be executed (step ST22). If no queued command is entered, the processing ends.

Which command is to be executed is determined in step ST22 as shown in FIG. 7 (subroutine as shown in FIG. 8).

As shown in FIG. 8, if a command associated with the bank #0 is entered, and the bank #0 is ready, the command associated with the bank #0 is determined as a candidate for a command to be executed (step ST31).

However, the above determination is made on condition that the command associated with the bank #0 is not a queued command. In the case where the command associated with the bank #0 is a queued command, and a subsequent command associated with the bank #0 is entered, even if queuing time set for the former command expires, the subsequent command is determined as a candidate for a command to be executed (step ST32).

Furthermore, if a command associated with the bank #1 is entered, and the bank #1 is ready, the command associated with the bank #1 is determined as a candidate for a command to be executed (step ST33).

However, the above determination is made on condition that the command associated with the bank #1 is not a queued command. Also, in the case where the command associated with the bank #1 is a queued command, and a subsequent command associated with the bank #1 is entered, even if queuing time for the former command expires, the subsequent command is determined as a candidate for a command to be executed (step ST34).

Furthermore, it is confirmed which of the banks #0 and #1 has higher priority than the other (step ST35).

If the bank #0 has higher priority than the bank #1, an entered command associated with the bank #0 is determined as a command to be executed (step ST36). On the other hand, if the bank #1 has higher priority than the bank #0, the entered command associated with the bank #1 is determined as a command to be executed (step ST39).

It should be noted that in steps ST 33 and 34, if the answer is no, the entered command associated with the bank #0 is determined as a command to be executed (route from step ST33 or ST34 to step ST36).

If no command associated with the bank #0 is entered, and the bank #0 is busy, or an entered command associated with the bank #0 is a queued command, and queuing time set for the entered command does not expire, it is confirmed whether a command associated with the bank #1 is entered or not (route from step ST31 or ST32 to step ST37).

If a command associated with the bank #1 is entered, and the bank #1 is ready, the command associated with the bank #1 is determined as a command to be executed (step ST37).

However, the above determination is made on condition that the entered command associated with the bank #1 is not a queued command. In the case where the entered command associated with the bank #1 is a queued command, and a subsequent command associated with the bank #1 is entered, even if queuing time set for the former command expires, the subsequent command is determined as a command to be executed (step ST38).

If no entered command to be executed is present, the above subroutine is repeated until a command is entered and determined as a command to be executed.

If the entered command is determined as the command to be executed, the processing to be executed is returned to the processing of the flow shown in FIG. 7.

Then, as shown in FIG. 7, it is confirmed whether the entered command to be executed is a write command or a read command (steps ST23 and ST27).

If the entered command to be executed is a write command, and it is indicated that parity data is to be generated (for example, an associated flag F1 as shown in FIG. 6 is set), parity data is generated by the parity controller (steps ST24 and ST25).

Furthermore, in parallel with generation of the parity data, the parity data is written (step ST26). On the other hand, if the entered command to be executed is a read command, and it is indicated that parity data is to be generated, parity data is generated by the parity controller (steps ST28 and ST29).

Furthermore, in parallel with generation of the parity data, the parity data is read (step ST30).

If the entered command to be executed is neither a write command nor a read command, it is transferred to the memory (step ST31).

(3) Example of Timing of Generating Parity Data

It will be explained by way of example at what timing parity data is generated in the case where the memory controller controls a plurality of banks.

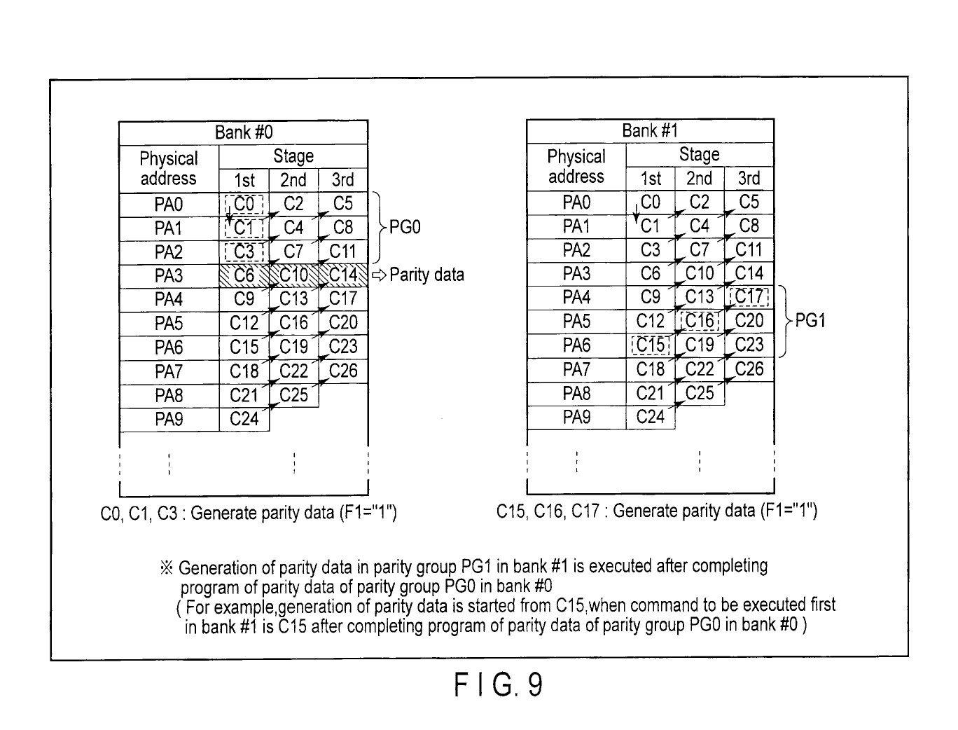

FIGS. 9 to 11 show an example of the timing of generating parity data.

Those figures are associated with FIG. 3. Also, in the figures, arrows indicate orders in which the commands C0 to C26 are executed.

In an example shown in FIG. 9, parity data associated with the parity group PG1 in the bank #1 is generated after the parity data associated with the parity group PG0 in the bank #0 is completely stored.

That is, the timing of generating the parity data associated with the parity group PG1 in the bank #1 is changed in accordance with whether the parity data associated the parity group PG0 in the bank #0 has been completely stored or not.

For example, storing of the parity data associated with the parity group PG0 in the bank #0 ends if execution of the command C14 to the bank #0 is completed. Therefore, after execution of the command C14 to the bank #0 is completed, if a command associated with the bank #1, which is to be executed first therefor, is the command C15, generation of parity data associated with the parity group PG1 in the bank #1 is started at the time of executing the command C15 or any command subsequent to the command C15.

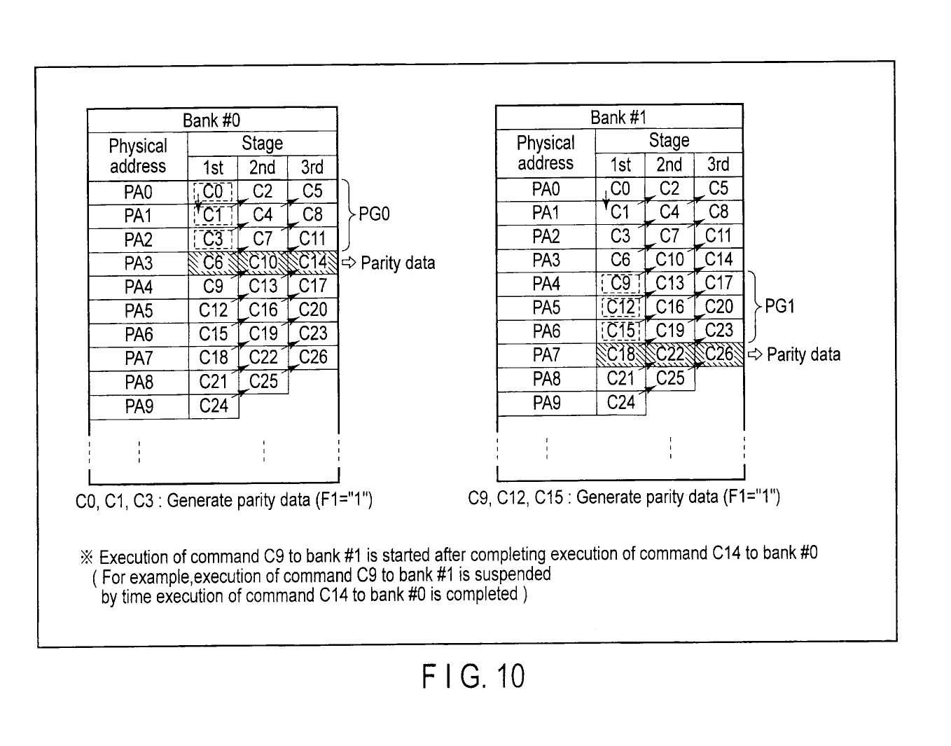

In an example shown in FIG. 10, parity data associated with the parity group PG1 in the bank #1 is generated after the parity data associated with the parity group PG0 in the bank #0 is completely stored, as in the example shown in FIG. 9.

However, in the second embodiment, the parity data associated with the parity group PG1 in the bank #1 is generated in execution of the commands C9, C12 and C15, and execution of the command C9 to the bank #1 is temporarily stopped until the parity data associated with the parity group PG0 in the bank #0 is completely stored, i.e., until execution of the command C14 to the bank #0 is completed.

For example, storing of the parity data associated with the parity group PG0 in the bank #0 ends when execution of the command C14 to the bank #0 is completed. Therefore, before completion of execution of the command C14 to the bank #0, execution of the command C9 to the bank #1 is temporarily stopped, and after completion of execution of the command C14 to the bank #0, execution of the command C9 to the bank #1 is started.

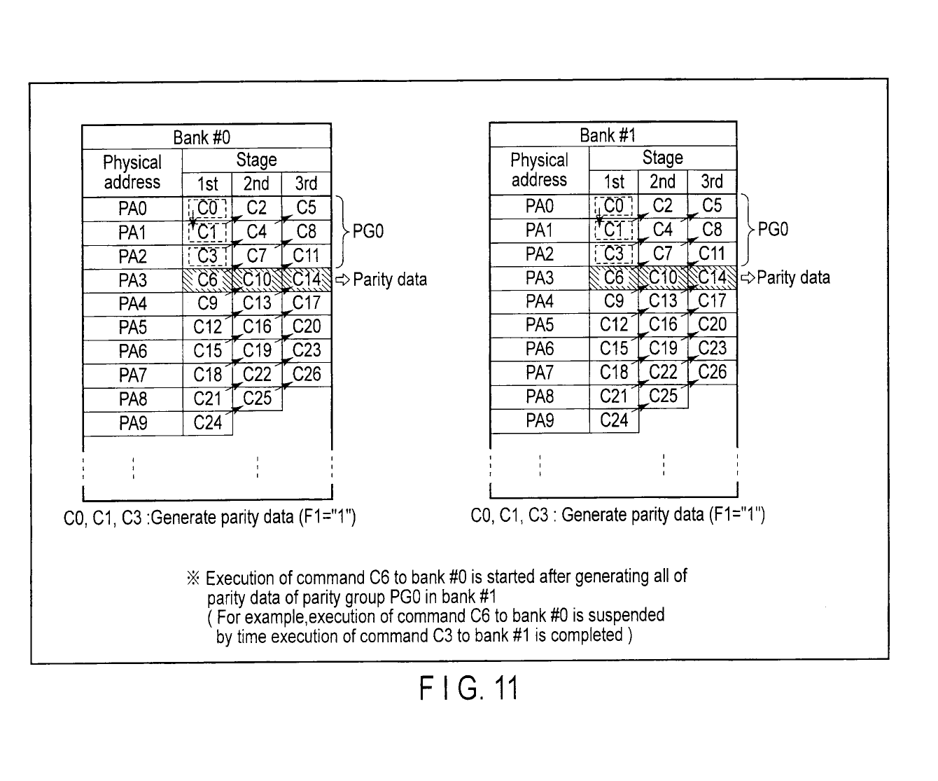

In an example shown in FIG. 11, the parity data associated with the parity group PG0 in the bank #0 is stored after the parity data associated with the parity group PG0 in the bank #1 is all generated. To be more specific, after the parity data associated with the parity group PG0 in the bank #0 is all generated, and then the parity data associated with the parity group PG0 in the bank #1 is all generated, storing of the parity data in the parity group PG0 in the bank #0 is started.

For example, storing of the parity data associated with the parity group PG0 in the bank #0 is started from execution of the command C6 to the bank #0. Therefore, until the parity data in the parity group PG0 in the bank #1 is all generated, i.e., until execution of the command C3 to the bank #1 is completed, execution of the command C6 to the bank #0 is temporarily stopped, and also after execution of the command C3 to the bank #1 is completed, execution of the command C6 to the bank #0 is started.

As described above, the parity data associated with the parity groups in the banks #0 and #1 can be generated at the same time by controlling the timing of generating/storing of the parity data.

(4) Conclusion

According to the second embodiment, write data and parity data can be transferred efficiently.

### 3. EXAMPLES OF APPLICATIONS

Examples of a data storage device to which the above first and second embodiment can be applied and a computer system provided with the data storage device will be explained.

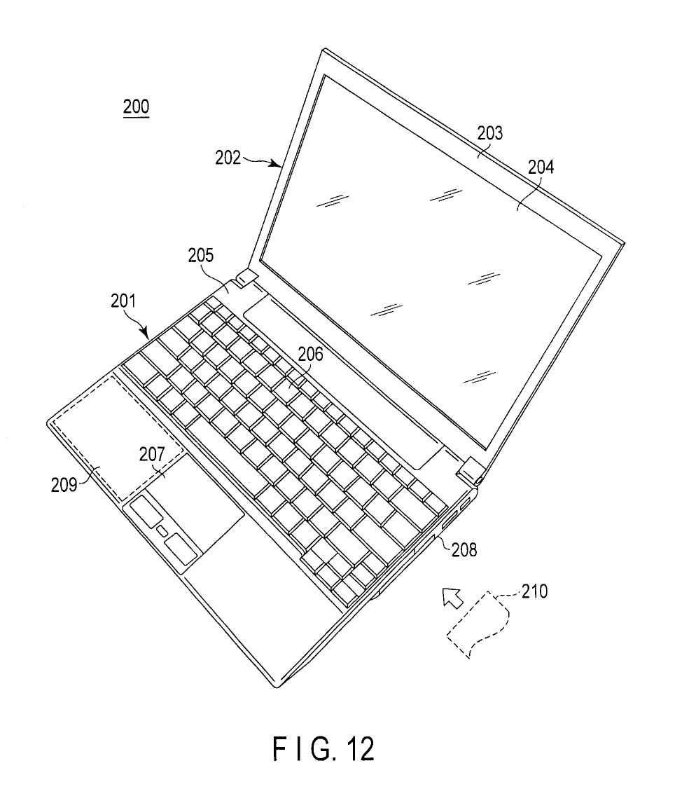

FIG. 12 shows an example of a portable computer including a data storage device.

To be more specific, a portable computer 200 comprises a main body 201 and a display unit 202. The display unit 202 comprises a display housing 203 and a display device 204 provided in the display housing 203.

The main body 201 comprises a housing 205, a keyboard 206 and a touch pad 207 which is a pointing device. The housing 205 includes a main circuit hoard, an optical disk device (ODD) unit, a card slot 208, a data storage device 209, etc.

The card slot 208 is provided in a side surface of the housing 205. The user can insert an additional device 210 into the card slot 208 from the outside of the housing 205.

The data storage device 209 is, for example, a solid-state drive (SSD). The SSD may be used after provided in the portable computer 200, instead of a hard disk drive (HDD). Also, the SSD may be used as the additional device 210. The data storage device 209 includes a memory controller 502 as explained with respect to the first and second embodiment and a nonvolatile memory which is controlled by the memory controller.

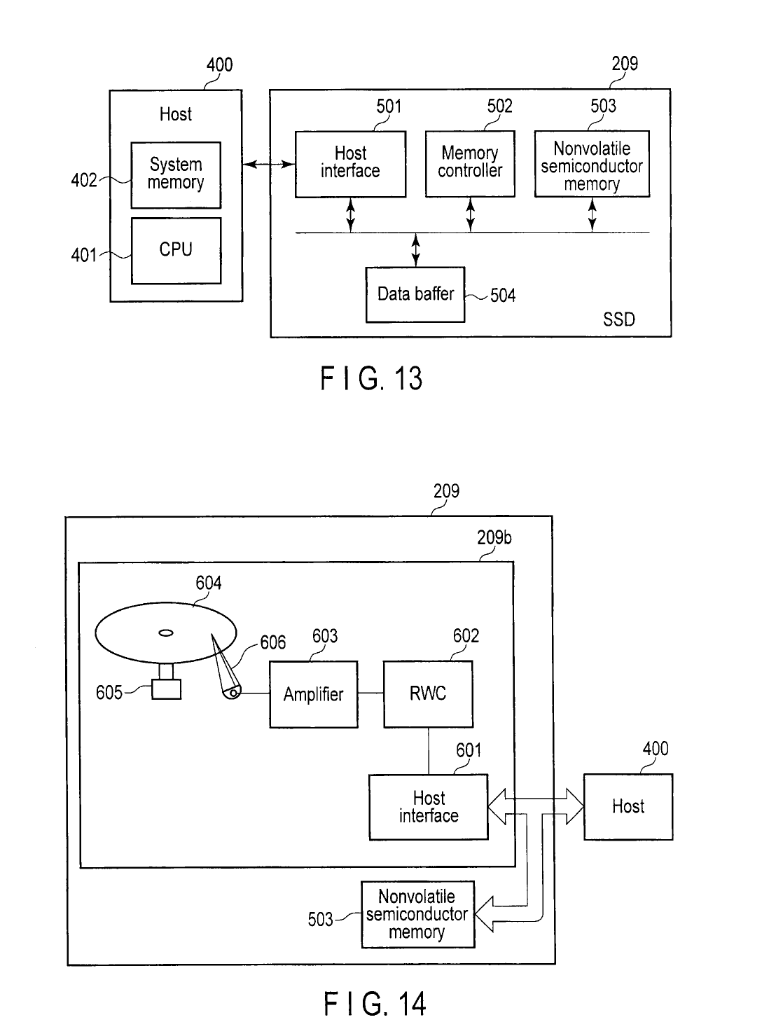

FIG. 13 shows an example of a data storage device.

The data storage device 209 is an SSD, and comprises a host interface 501, the memory controller 502, a nonvolatile semiconductor memory 503 and a data buffer 504.

The host interface 501 functions as an interface between a host 400 and the data storage device 209. The host 400 comprises a CPU 401 and a system memory 402.

The nonvolatile memory 503 is, for example, a NAND flash memory. The data buffer 503 is, for example, a DRAM or an MRAM. That is, the data storage device 209 is an SSD, and comprises the host interface 501, the memory controller 502, the nonvolatile semiconductor memory 503, and the data buffer 504.

The memory controller 502 controls reading from, writing to, and erasure of the nonvolatile semiconductor memory 503.

FIG. 14 shows an example of a hybrid data storage device.

A data storage device 209 comprises a nonvolatile semiconductor memory 503 and an HDD 209b. The HDD 209h comprises a host interface 601, a read write channel (RWC) 602, an amplifier 603, a magnetic disk 604, a disk drive device 605 and an actuator 606 including a magnetic head.

The disk drive device 606 rotates the magnetic disk 604. The amplifier 603 amplifies a signal read by the magnetic head in the actuator 606. In reading, the RWC 602 transfers the signal output from the amplifier 603 to the host interface 601, and in writing, the RWC 602 transfers a signal from the host interface 601 to the amplifier 603.

The host 400 controls reading from, writing to, and erasure of the nonvolatile semiconductor memory 503 and also reading from, writing to, and erasure of the HDD 209b. The writing according to the first and second embodiments is performed, for example, when the nonvolatile semiconductor memory 503 is selected.

It should be noted that the reading from, writing to, and erasure of the nonvolatile semiconductor memory 503 may be controlled by the host interface 601, instead of by the host 400. Also, the first and second embodiments can be applied to a memory card incorporating a NAND flash memory. Also, in addition to the above devices, the first and second embodiments can be applied to various memory systems such as a cell phone, a personal digital assistant (PDA), a digital still camera and a digital video camera.

### 4. CONCLUSION

According to the above embodiments, it is possible to transfer write data and parity data efficiently.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory controller comprising:
a bank controller comprising a queuing part configured to queue commands associated with a bank and having a first flag associated with each of the commands, the bank controller executing the commands in order;
a data controller configured to transfer write data to the bank when a particular command to be executed among the commands is a write command associated with one of physical addresses in the bank; and
a parity controller configured to generate parity data for restoring the write data based on a value of a first flag associated with the particular command by a time the particular command is completed,
wherein a write associated with each physical addresses is executed by stages,
parity data for restoring write data of the physical addresses is generated in an initial stage among the stages when the physical addresses are included in an initial parity group, and
parity data for restoring write data of the physical addresses is generated in an any stage among the stages when the physical addresses are included in a parity group except the initial parity group.

2. The controller of claim 1, wherein
the queuing part comprises a second flag associated with each of the commands, and
the data controller transfers the parity data to the bank based on a value of the second flag associated with the particular command to be executed.

3. The controller of claim 2, wherein
each of the physical addresses comprises first to n^{th} logical addresses, where n is a natural number equal to or larger than 2.

4. The controller of claim 3, wherein the write data comprises write data to be written to the first to n^{th} logical addresses, and is transferred n times to one of the physical addresses.

5. The controller of claim 1, wherein
parity data for restoring write data for first to n^{th} physical addresses among the physical addresses is written to a (n+1)^{th} physical address among the physical addresses.

6. The controller of claim 1, wherein
the parity controller generates parity data for restoring the write data before execution of the particular command is completed, when the first flag associated with the particular command is active.

7. The controller of claim 6, wherein
the particular command to be executed changes in order of a first write command associated with a first physical address, a second write command associated with a second physical address, and a third write command associated with the first physical address.

8. The controller of claim 7, wherein
a first flag associated with each of the first and second write commands is active.

9. The controller of claim 1, wherein
the data controller transfers the parity data to the bank before execution of the particular command is completed, when the second flag associated with the particular command is active.

10. The controller of claim 1, wherein
the parity data for restoring the write data of the other physical addresses is generated in different stages for each physical addresses, when the other physical addresses are included in the parity group except the initial parity group.

11. The controller of claim 1, wherein
the bank controller stops or restarts execution of the commands to the bank based on an executed state of commands associated with another bank.

12. A data storage device comprising:
a nonvolatile semiconductor memory; and
a memory controller controlling the nonvolatile semiconductor memory, wherein
the memory controller comprising:
a bank controller comprising:
a queuing part configured to queue commands associated with a bank and having a first flag associated with each of the commands, the bank controller executing the commands in order;
a data controller configured to transfer write data to the bank when a particular command to be executed among the commands is a write command associated with one of physical addresses in the bank; and
a parity controller configured to generate parity data for restoring the write data based on a value of a first flag associated with the particular command by a time the particular command is completed,
wherein a write associated with each physical address is executed by stages,
parity data for restoring write data of the physical addresses is generated in an initial stage among the stages when the physical addresses are included in an initial parity group, and
parity data for restoring write data of the physical addresses is generated in an any stage among the stages when the physical addresses are included in a parity group except the initial parity group.

13. The device of claim 12, wherein
the queuing part comprises a second flag associated with each of the commands, and
the data controller transfers the parity data to the bank based on a value of the second flag associated with the particular command to be executed.

14. The controller of claim 13, wherein
each of the physical addresses comprises first to n^{th} logical addresses, where n is a natural number equal to or larger than 2.

15. The controller of claim 14, wherein the write data comprises write data to be written to the first to n^{th} logical addresses, and is transferred n times to one of the physical addresses.

16. The device of claim 12, wherein
the nonvolatile semiconductor memory comprises a NAND flash memory.

17. A data write method for physical addresses in a bank, each of which includes logical addresses, the method comprising:
executing writing associated with each of the physical addresses by stages;
generating parity data for restoring write data of the physical addresses in an initial stage among the stages, when the physical addresses are included in an initial parity group; and
generating parity data for restoring write data of the other physical addresses in an any stage among the stages, when the other physical addresses are included in a parity group except the initial parity group.

18. The method of claim 17, wherein
write data associated with logical addresses is transferred to the bank in writing of each of the stages.

19. The method of claim 17, wherein
the parity data for restoring the write data of the other physical addresses is generated in different stages for each physical addresses, when the other physical addresses are included in the parity group except the initial parity group.

20. The method of claim 17, wherein
execution of the commands to the bank is stopped or restarted based on an executed state of commands associated with another bank.
